(19) United States
(12) Patent Application Publication
(10) Pub. No.: US 2010/0310972 A1
(43) Pub. Date: Dec. 9, 2010

(54) PERFORMING DOUBLE EXPOSURE PHOTOLITHOGRAPHY USING A SINGLE RETICLE

(76) Inventor: Jason P. Cain, Austin, TX (US)

Correspondence Address: WILLIAMS, MORGAN & AMERSON, 10333 RICHMOND, SUITE 1100, HOUSTON, TX, 77042, US

(21) Appl. No.: 12/477,474

(22) Filed: Jun. 3, 2009

(51) Int. Cl. G03F 1/00; G03F 7/20; G03B 27/54

(52) U.S. Cl. 430/5; 430/322; 355/67

(57) ABSTRACT

A reticle includes a first pattern formed in a first die flash region of the reticle and a second pattern different than the first pattern formed in a second die flash region of the reticle. A method for patterning a wafer having a plurality of die regions defined thereon includes exposing a first die region using a first pattern formed on a reticle during a first exposure, repositioning the reticle, and exposing the first die region using a second pattern formed on the reticle during a second exposure.

### CROSS-REFERENCE TO RELATED APPLICATIONS

Not applicable.

### STATEMENT REGARDING FEDERALLY SPONSORED RESEARCH OR DEVELOPMENT

Not applicable

### BACKGROUND

The disclosed subject matter relates generally to semiconductor device manufacturing and, more particularly, to a method and apparatus for performing double exposure photolithography using a single reticle.

Semiconductor devices, or microchips, are manufactured from wafers of a substrate material. Layers of materials are added, removed, and/or treated during fabrication to create the integrated, electrical circuits that make up the device. The fabrication essentially comprises four operations: layering, or adding thin layers of various materials to a wafer from which a semiconductor is produced; patterning, or removing selected portions of added layers; doping, or placing specific amounts of dopants in the wafer surface through openings in the added layers; and heat treatment, or heating and cooling the materials to produce desired effects in the processed wafer. Although there are only four basic operations, they can be combined in hundreds of different ways, depending upon the particular fabrication process.

The fabrication process generally involves processing a number of wafers through a series of fabrication tools. Each fabrication tool performs one or more of the four basic operations. The four basic operations are performed in accordance with an overall process to finally produce wafers from which the semiconductor devices are obtained.

Of these four operations, patterning is considered to be an important step. Patterning is known to those in the art by many names. Other names for patterning include photolithography, photomasking, masking, oxide removal, metal removal, and microlithography. The term “photolithography” will hereafter be used to refer to patterning operations. Photolithography typically involves a machine called an “exposure tool,” or sometimes also called a “stepper” or a “scanner”. An exposure tool positions a portion of a wafer being processed under a “photomask.” The photomask is usually a reticle, which is a copy of a pattern created in a layer of chrome on a glass plate. Light is then transmitted through the reticle onto a thin layer of material called photoresist previously added to the wafer. The chrome blocks the light while the glass allows it to pass.

The light shining through the pattern on the reticle creates an aerial image which, when interfacing with the photoresist at the optimum focal plane, changes the material characteristics of the photoresist where it shines. In essence, this allows the pattern on the reticle to be duplicated in, or transferred to, the photoresist. The change in material characteristics makes the photoresist susceptible to removal in the subsequent develop operation prior to the next sequential process step such as etching or ion implantation. The exposure tool then positions another portion of the wafer under the reticle, and the pattern transfer is repeated. The process is repeated until the entire wafer has completed the pattern transfer operation. This process of shining light through a photomask to treat a photoresist is known as “exposure,” or “pattern transfer.”

The reticle described in the example above is more precisely known as a “binary mask” because each portion of the reticle either transmits all the light or blocks all the light. However, ever-decreasing feature sizes have created problems for binary masks. The light shining through the chrome pattern scatters at the edges of the chrome traces, with undesirable effects on the pattern transfer process to the photoresist. The smaller the feature sizes, the more acute the problem.

Another type of photomask is a “phase shift” photomask. There are a variety of phase shift photomask types, but all shift the phase of the light waves so that the projected image of the photomask has an improvement of one or more image characteristics (e.g., contrast, edge definition, etc.) as compared with the same pattern from a binary photomask. An attenuated phase shift photomask, for instance, comprises a reticle that attenuates and phase-shifts the light wave in the “dark” regions of the photomask so that the contrast between bright and dark regions of the image is improved. Since, the transmission function of such a photomask cannot be described in simple terms of “bright” or “dark,” this type of mask is not considered “binary.” A complementary phase shift photomask actually comprises two reticles, where, at most, only one of which can be binary. The first (i.e., typically binary) is used to define an exposure area and to expose noncritical features, and the second (i.e., typically phase-shifting) is used to expose the critical features in a second pass. Both passes are performed before the wafer is stepped to process another portion of the wafer so that the wafers are not exposed, developed, baked, and etched twice.

Optical lithography systems all share a fundamental physical limitation on the minimum pitch (i.e., the center-to-center space of two adjacent features) that can be resolved. This limit is a function of the illumination wavelength and the numerical aperture (NA) of the exposure tool. One way to overcome this limitation is to superimpose two images, each of which may be at the pitch resolution limit. By printing two separate images at the minimum pitch but with a lateral shift of one-half the pitch value between them, the effective pitch resolution can be doubled.

An example double exposure photolithography technique, which may be employed with binary or phase shifting reticles, involves exposing a photoresist layer with a first reticle of a reticle pair and then separately exposing the same photoresist layer with a second reticle of the reticle pair. One advantage of double exposure photolithography is that when two individual patterns that are each at the maximum pitch resolution of the system are interleaved, the effective resolution is doubled for the combined image. The use of two reticles for a double exposure photolithography process increases cost due to the additional reticles that need to be purchased by the manufacturer and also a reduction in throughput as multiple exposures are required. Moreover, each reticle must be individually loaded and aligned. Misalignment between the first and second reticles can cause a reduction in the performance of the devices or can result in the devices being faulty and requiring them to be subsequently scrapped.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY

The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in a reticle including a first pattern formed in a first die flash region of the reticle and a second pattern different than the first pattern formed in a second die flash region of the reticle.

Another aspect of the disclosed subject matter is seen in a method for patterning a wafer having a plurality of die regions defined thereon. The method includes exposing a first die region using a first pattern formed on a reticle during a first exposure, repositioning the reticle, and exposing the first die region using a second pattern formed on the reticle during a second exposure.

Yet another aspect of the disclosed subject matter is seen in a method for patterning a wafer having a plurality of die regions defined thereon. The method includes providing a reticle having a first pattern formed in a first die flash region of the reticle and a second pattern different than the first pattern formed in a second die flash region of the reticle. The reticle is positioned to align the first die flash region with a first die region of the wafer, and the first die region is exposed using the reticle during a first exposure. The reticle is repositioned to align the first die flash region with a second die region and the second die flash region with the first die region, and the first and second die regions are exposed using the reticle during a second exposure.

Still another aspect of the disclosed subject matter is seen in a system for patterning a wafer including a reticle, a light source, and an alignment system. The reticle has a first pattern formed in a first die flash region of the reticle and a second pattern different than the first pattern formed in a second die flash region of the reticle. The light source is operable to provide electromagnetic energy for exposing the wafer through the reticle. The alignment system is operable to align the reticle with selected positions on the wafer, and move the reticle by half steps between exposures of the wafer.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1 is a simplified block diagram of a photolithography system in accordance with one illustrative embodiment of the present subject matter;

FIG. 2 is a simplified diagram of a reticle that may be used in the system of FIG. 1;

FIGS. 3A-3E illustrate how the reticle of FIG. 2 may be employed to perform double exposure photolithography; and

FIGS. 4A-4C illustrate alternative reticle layouts.

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

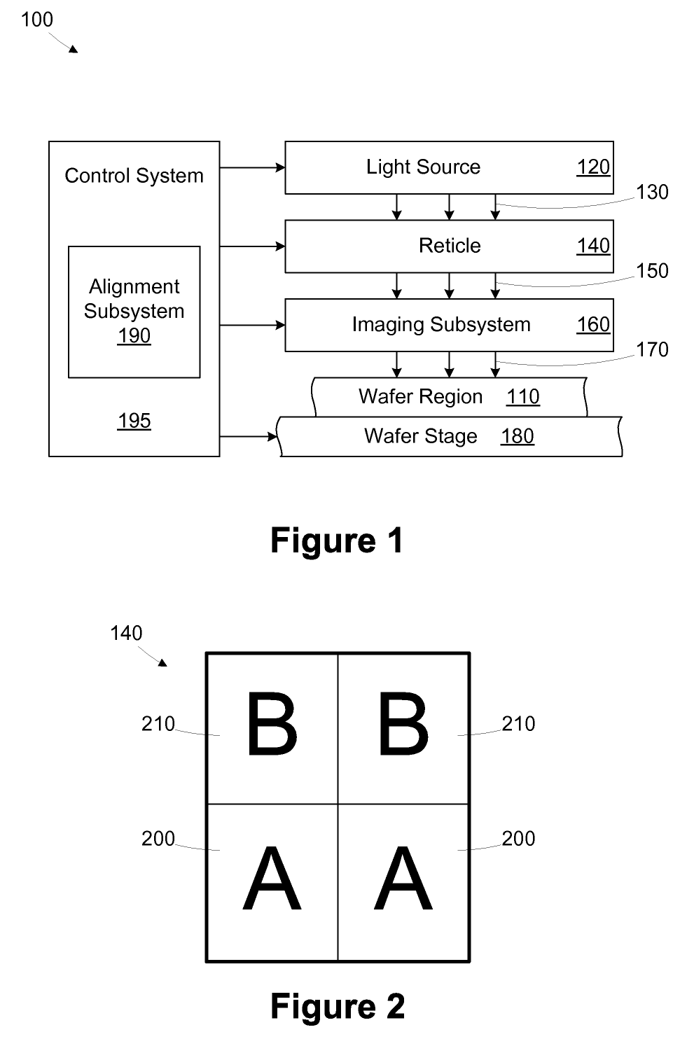

Referring now to the drawings wherein like reference numbers correspond to similar components throughout the several views and, specifically, referring to FIG. 1, the disclosed subject matter shall be described in the context of a photolithography system 100 for imaging a pattern onto a wafer 110, or a region thereof. The system 100 can be, for example, a step-and-repeat exposure system or a step-and-scan exposure system, but is not limited to these example systems. The system 100 includes include a light source 120 for directing light energy 130 towards a reticle 140. The light energy 130 can have, for example, a deep ultraviolet (DUV) wavelength (e.g., about 248 nm or about 193 nm), a vacuum ultraviolet (VUV) wavelength (e.g., about 157 nm), or an extreme ultraviolet (EUV) wavelength (e.g., about 13.4 nm).

The reticle 140, which can be mounted on a stage or chuck (not shown) selectively blocks light energy 130 (or, in the case of an EUV wavelength, selectively reflects radiation) such that a light energy pattern 150 defined by the reticle 140 is transferred towards the wafer 110. An imaging subsystem 160, such as a stepper assembly or a scanner assembly, sequentially directs the energy pattern 150 transmitted by the reticle 140 to a series of desired locations on the wafer 110. The imaging subsystem 160 may include a series of lenses and/or reflectors for use in scaling and directing the energy pattern 150 towards the wafer 110 in the form of an imaging (or exposure) light energy pattern 170.

The wafer 110 may be mounted on a wafer stage 180. In one embodiment, the wafer stage 180 can be moved relative to the imaging subsystem 160 so as to place a desired portion of the wafer 110 in the path of the exposure pattern 24. Alternatively, the imaging optics can be movable and/or the exposure pattern can be optically retargeted. To assist in aligning the wafer 110 with respect to the exposure pattern 170, the lithography system 100 includes an alignment subsystem 190. The alignment subsystem 190 may be a part of a general control system 195 for the lithography system 100.

Turning now to FIG. 2, a simplified diagram of the reticle 140 is provided. The reticle 140 is adapted to perform double exposure photolithography using a single reticle. To that end, the reticle 140 includes a first reticle pattern (i.e., pattern “A”) and a second reticle pattern (i.e., pattern “B”) defined in different die flash regions 200, 210 of the reticle 140. A die flash region 210, 220 is considered to be a region of the reticle that is used to expose one die on the wafer. Hence, a particular die location on the wafer can be exposed with either the A pattern or the B pattern depending on the position of the reticle 140.

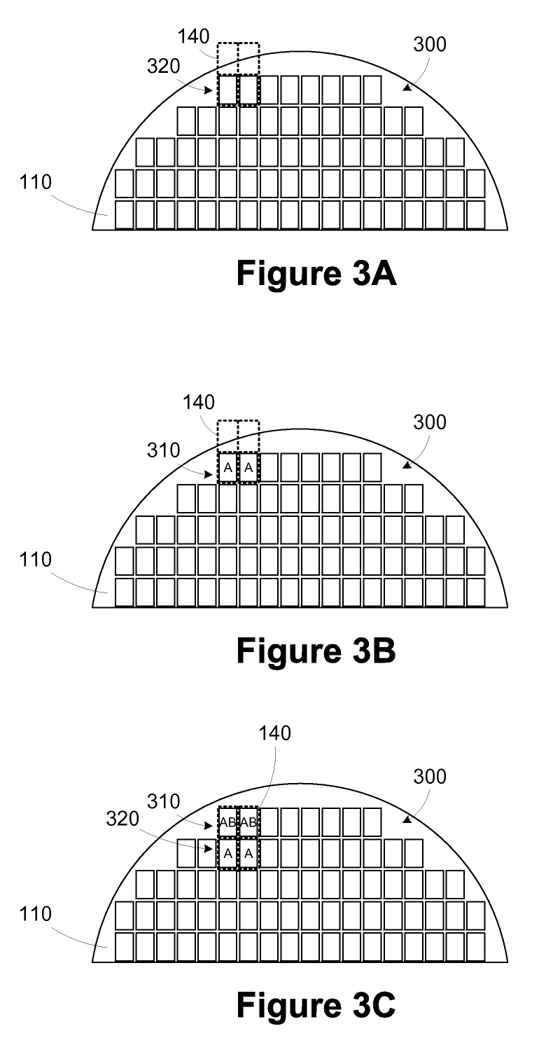

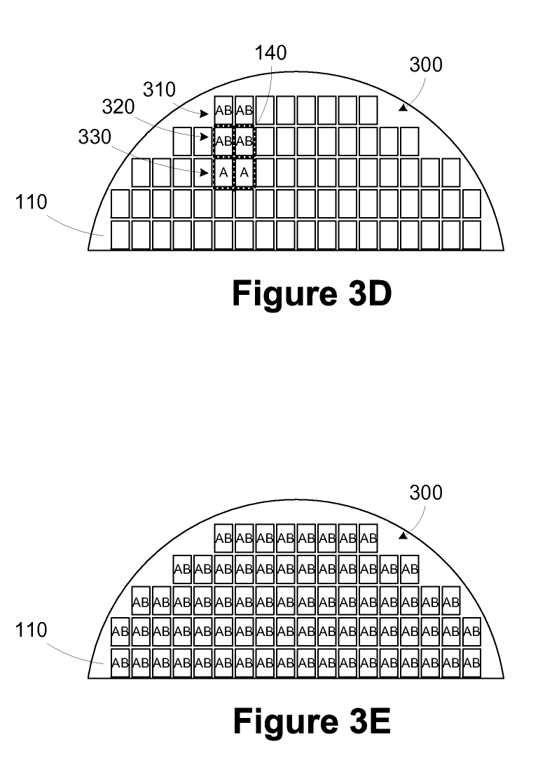

In the illustrated embodiment, the reticle 140 is a 2×2 reticle. The lower patterns are of type A, and the upper patterns are of type B. The reticle type may vary. For example, both A and B patterns may be binary patterns, both may be phase shift patterns, or they may be a combination of binary and phase shift patterns. The use of the reticle to achieve double exposure photolithography is described in greater detail below with reference to FIGS. 3A-3E.

FIG. 3A shows a portion of a wafer 110. Die regions 300 are generally arranged in a grid pattern. The reticle 140 is positioned by the imaging subsystem 160 so that it partially overlaps the grid at die positions 310, and the wafer 110 is exposed. As shown in FIG. 3B, the die positions 310 that were exposed using the reticle 140 are patterned with pattern A. The portions of the reticle 140 having pattern B expose an unused portion of the wafer 110.

After the first flash, the reticle 140 is repositioned by a half step to overlie the two previously exposed die positions 310 and the next two die positions 320. The movement is referred to a half step, in contrast to a conventional full step movement where the reticle would be moved to a new flash position that does not overlap the previous flash position. After a second flash, the die positions 310 receive the full double exposure pattern “AB” and the die positions 320 receive the A pattern, as shown in FIG. 3C.

The imaging subsystem 160 moves the reticle 140 another half step and flashes the wafer 110 to pattern the die positions 32 with the full AB pattern and the die positions 330 with the A pattern, as shown in FIG. 3D.

The half step exposure pattern continues until all die regions 300 have been patterned by both the A and B portions of the reticle, as shown in FIG. 3E. At the lower boundary of the wafer 110 and/or the left/right boundaries, the reticle 140 would only partially overlap the die regions 300.

The arrangement of the A and B patterns on the reticle 140 and the associated stepping pattern may vary depending on the size and arrangement of the die regions 300 and the configuration of the photolithography system 100. In general, any M×N configuration may be used that has an axis about which the patterns oppose each other to allow a half step exposure to be performed.

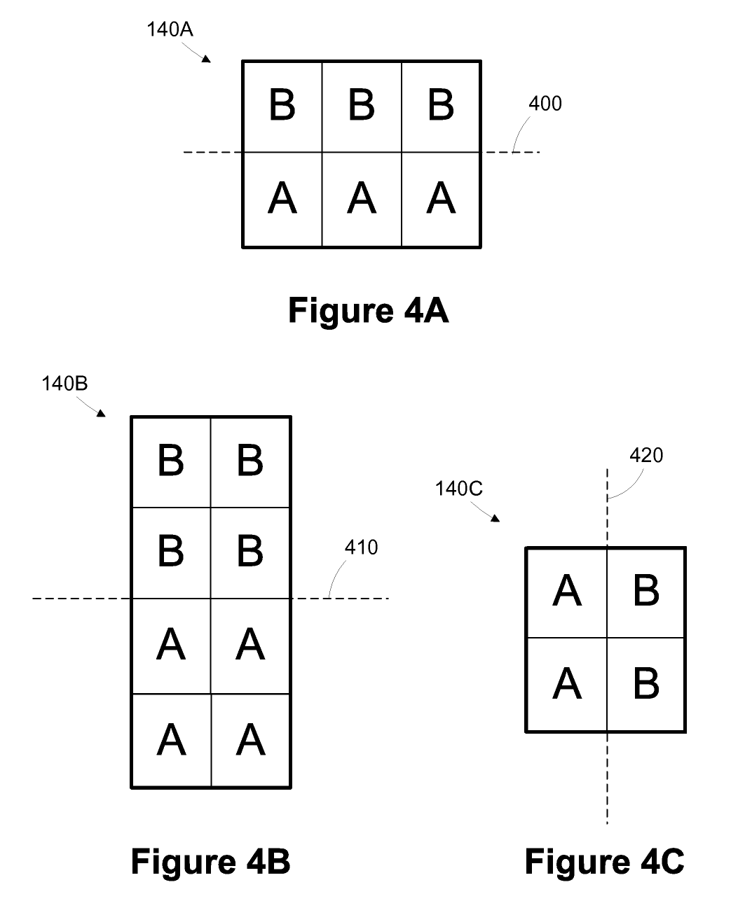

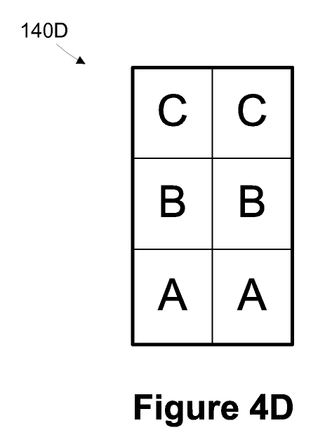

FIGS. 4A-4D illustrate exemplary reticle configurations. The reticle 140A of FIG. 4A has a 2×3 configuration, with the A and B patterns being arranged opposed to a horizontal half step axis 400. The reticle 140B of FIG. 4B has a 2×4 configuration and a horizontal half step axis 410. The reticle 140C has a 2×2 arrangement of patterns that oppose each other around a vertical half step axis 420. The reticle 140C is suitable for use with a scanner that uses a horizontal stepping pattern. Moreover, the number of patterns defined on the reticle 140 may vary. For example, a three pass photolithography technique may employ a reticle with “A”, “B”, and “C” images, as shown in the reticle 140D of FIG. 4D.

The dual pattern reticle 140 and double exposure stepping techniques herein provide the advantages of a dual exposure photolithography without requiring additional reticles, reticle change-outs, or realignment. These advantages result in increased throughput and reduced error, which correspond generally to increased performance and profitability.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. A reticle, comprising:
a first pattern formed in a first die flash region of the reticle; and
a second pattern different than the first pattern formed in a second die flash region of the reticle.

2. The reticle of claim 1, further comprising:
a third pattern matching the first pattern formed in a third die flash region of the reticle; and
a fourth pattern matching the second pattern formed in a fourth die flash region of the reticle, wherein the first and third patterns form a first group, the second and fourth patterns form a second group, and the first and second groups oppose one another about an axis.

3. The reticle of claim 1, wherein the first and second patterns comprise binary patterns.

4. The reticle of claim 1, wherein the first and second patterns comprise phase shift patterns.

5. The reticle of claim 1, wherein one of the first and second patterns comprises a binary pattern, and the other of the first and second patterns comprises a phase shift pattern.

6. The reticle of claim 1, further comprising a third pattern different than the first and second patterns formed in a third die flash region of the reticle.

7. A method for patterning a wafer having a plurality of die regions defined thereon, comprising:
exposing a first die region using a first pattern formed on a reticle during a first exposure;
repositioning the reticle;
exposing the first die region using a second pattern formed on the reticle during a second exposure.

8. The method of claim 7, further comprising exposing a third die region using the second pattern during the first exposure.

9. The method of claim 8, further comprising exposing a fourth die region using the first pattern during the second exposure.

10. The method of claim 7, wherein repositioning the reticle comprises repositioning the reticle by a half step.

11. The method of claim 7, further comprising:
repositioning the reticle after exposing the first die region using the second pattern; and
exposing the first die region using a third pattern formed on the reticle during a third exposure.

12. A method for patterning a wafer having a plurality of die regions defined thereon, comprising:
providing a reticle having a first pattern formed in a first die flash region of the reticle and a second pattern different than the first pattern formed in a second die flash region of the reticle;
positioning the reticle to align the first die flash region with a first die region of the wafer;
exposing the first die region using the reticle during a first exposure;
repositioning the reticle to align the first die flash region with a second die region and the second die flash region with the first die region; and
exposing the first and second die regions using the reticle during a second exposure.

13. The method of claim 12, wherein positioning the reticle comprises positioning the reticle to align the second die flash region with an unused region of the wafer.

14. The method of claim 12, further comprising repositioning the reticle by half steps between subsequent exposures to expose a plurality of die regions with the first and second patterns.

15. The method of claim 12, wherein providing the reticle further comprises providing the reticle having a third pattern different than the first and second patterns formed in a third die flash region of the reticle, and the method further comprises:
repositioning the reticle to align the first die flash region with a third die region, the second die flash region with the second die region, and the third die flash region with the first die region; and
exposing the first, second, and third die regions using the reticle during a third exposure.

16. A system for patterning a wafer, comprising:
a reticle having at least a first pattern formed in a first die flash region of the reticle and at least a second pattern different than the first pattern formed in a second die flash region of the reticle;
a light source operable to provide electromagnetic energy for exposing the wafer through the reticle; and
an alignment system operable to align the reticle with selected positions on the wafer, and move the reticle by partial steps between exposures of the wafer.

17. The system of claim 16, wherein the alignment system is operable to position the reticle to align the first die flash region with a first die region of the wafer to allow the light source to expose the first die region during a first exposure, reposition the reticle to align the first die flash region with a second die region and the second die flash region with the first die region to allow the light source to expose the first and second die regions during a second exposure.

18. The system of claim 17, wherein the alignment system is operable to position the reticle to align the second die flash region with an unused region of the wafer during the first exposure.

19. The system of claim 16, wherein the first and second patterns comprise binary patterns.

20. The system of claim 16, wherein the first and second patterns comprise phase shift patterns.

21. The system of claim 16, wherein one of the first and second patterns comprises a binary pattern, and the other of the first and second patterns comprises a phase shift pattern.
